(19) United States
(12) Patent Application Publication
(10) Pub. No.: US 2026/0114105 A1
(43) Pub. Date: Apr. 23, 2026

(54) DISPLAY DEVICE

(71) Applicant: Samsung Display Co., Ltd., Yongin-si (KR)

(72) Inventors: SANGHYUNG LIM, Yongin-si (KR); TAEGYUN KIM, Yongin-si (KR); Youngchul SIM, Yongin-si (KR); JAEHO CHOI, Yongin-si (KR)

(21) Appl. No.: 19/359,860

(22) Filed: Oct. 16, 2025

(30) Foreign Application Priority Data
Oct. 23, 2024 (KR) 10-2024-0145423

(51) Int. Cl. H10H 29/855; H10H 29/39; H10H 29/80

(52) U.S. Cl. CPC H10H 29/855; H10H 29/39; H10H 29/842

(57) ABSTRACT

A display device includes a complementary metal oxide semiconductor (CMOS) wafer including a display area including unit areas and a boundary area between the unit areas, the display area having a lattice shape and a non-display area adjacent to the display area, light emitting diodes overlapping the unit areas, a flattening layer covering the light emitting diodes, an auxiliary electrode overlapping the boundary area and located in the flattening layer, a common electrode on the flattening layer and connected to the auxiliary electrode and the light emitting diodes, and a passivation layer covering the common electrode, wherein grooves recessed in a direction from an upper surface of the flattening layer toward the light emitting diodes are in the flattening layer overlapping the unit areas.

### CROSS-REFERENCE TO RELATED APPLICATION

The present application claims priority to and the benefit of Korean Patent Application No. 10-2024-0145423, filed on Oct. 23, 2024, in the Korean Intellectual Property Office, the entire disclosure of which is incorporated by reference herein.

### BACKGROUND

Embodiments of the present disclosure described herein relate to a display device, and more particularly, relate to a display device including a complementary metal oxide semiconductor (CMOS) wafer and a light emitting diode.

Electronic devices such as smartphones, laptop computers, navigation systems, and smart televisions that provide images to a user include display devices for displaying the images. An augmented reality device, a virtual reality device, and a video projection device may include a micro display device. The micro display device may include a CMOS wafer and a light emitting diode disposed on the CMOS wafer to display a high-brightness image while driven by low power.

### SUMMARY

Embodiments of the present disclosure provide a display device having reduced light loss and reduced defects.

Further, embodiments of the present disclosure also provide a method of manufacturing a display device, in which manufacturing costs are reduced and a manufacturing process is simplified.

According to one or more embodiments, a display device includes a complementary metal oxide semiconductor (CMOS) wafer including a display area including unit areas and a boundary area between the unit areas, the display area having a lattice shape and a non-display area adjacent to the display area, light emitting diodes overlapping the unit areas, a flattening layer covering the light emitting diodes, an auxiliary electrode overlapping the boundary area and located in the flattening layer, a common electrode on the flattening layer and connected to the auxiliary electrode and the light emitting diodes, and a passivation layer covering the common electrode, wherein grooves recessed in a direction from an upper surface of the flattening layer toward the light emitting diodes are in the flattening layer overlapping the unit areas.

The display device may include lens patterns in the grooves, respectively.

The flattening layer may include a silicon oxide, and the lens patterns may include a silicon nitride.

A refractive index of the flattening layer may be greater than a refractive index of the lens patterns.

The refractive index of the flattening layer may be in a range of 1.5 to 1.6, and the refractive index of the lens patterns may be in a range of 1.4 to 1.5.

The lens patterns may have a relatively higher density than a density of the flattening layer.

An upper surface of the auxiliary electrode and upper surfaces of the lens patterns in contact with the common electrode may be in a same plane.

Each of the grooves on a cross section may have one of a semi-elliptical shape, a triangular shape, or a quadrangular shape.

A shape of each of the lens patterns on a cross section may have a shape corresponding to a shape of the groove.

The display device may further include a first side insulating layer covering the light emitting diodes and second side insulating layers arranged between the light emitting diodes and the first side insulating layer and covering the light emitting diodes.

The display device may further include a side reflective layer on the first side insulating layer and overlapping the light emitting diodes.

The common electrode may be connected to the light emitting diodes through an opening passing through the first side insulating layer, the second side insulating layer, the side reflective layer, the flattening layer, and the lens pattern.

The passivation layer may compensate for a step difference in the display device due to components arranged under the passivation layer, and an upper surface of the passivation layer may have a flat surface.

The common electrode may be in contact with the auxiliary electrode in the boundary area, may be in the grooves in the unit areas, and may be in contact with the flattening layer.

The flattening layer may include a silicon oxide, and the passivation layer may include a silicon nitride.

The passivation layer may be on the common electrode to correspond to a shape of the common electrode.

The display device may further include a lens layer on the passivation layer and overlapping the boundary area and the unit areas, wherein a refractive index of the lens layer may be smaller than a refractive index of the flattening layer.

The lens layer may be a mixture of an organic material and hollow silica.

A refractive index of the passivation layer may be equal to or smaller than the refractive index of the flattening layer.

The CMOS wafer may include a silicon substrate which is connected to the light emitting diodes and in which a source area or a drain area is defined, a gate on the silicon substrate, a first insulating layer covering the gate and on the silicon substrate, a first contact electrode connected to the source area or the drain area through a first contact hole defined in the first insulating layer, a second insulating layer covering the first contact electrode and on the first insulating layer, and a second contact electrode connected to the first contact electrode through a second contact hole passing through the second insulating layer.

An electronic device including a display device, the display device including: a complementary metal oxide semiconductor (CMOS) wafer including: a display area including unit areas and a boundary area between the unit areas, the display area having a lattice shape; and a non-display area adjacent to the display area; light emitting diodes overlapping the unit areas; a flattening layer covering the light emitting diodes; an auxiliary electrode overlapping the boundary area and located in the flattening layer; a common electrode on the flattening layer and connected to the auxiliary electrode and the light emitting diodes; and a passivation layer covering the common electrode, wherein grooves recessed in a direction from an upper surface of the flattening layer toward the light emitting diodes are in the flattening layer overlapping the unit areas.

A display device according to the present disclosure may include an auxiliary electrode connected to a common electrode, thereby reducing a voltage drop generated in the common electrode. Further, lens patterns may be arranged in grooves generated in a process of forming the auxiliary electrode, thereby reducing manufacturing costs and simplifying a manufacturing process.

### BRIEF DESCRIPTION OF THE DRAWINGS

FIG. 1 is a perspective view of a display device according to one or more embodiments of the present disclosure.

FIG. 2 is a view illustrating a cross section of the display device illustrated in FIG. 1.

FIG. 3 is a plan view in which a common electrode is disposed in a display area and a non-display area of the display device according to one or more embodiments of the present disclosure.

FIG. 4 is a plan view illustrating an arrangement relationship between a common electrode, a voltage transfer electrode, and auxiliary electrodes according to one or more embodiments of the present disclosure.

FIG. 5 is an enlarged plan view illustrating a partial area of the display area according to one or more embodiments of the present disclosure.

FIG. 6 is a cross-sectional view taken along the line I-I′ of FIG. 5.

FIG. 7A is a perspective view of a light emitting diode according to one or more embodiments of the present disclosure.

FIG. 7B is a perspective view of the light emitting diode according to one or more embodiments of the present disclosure.

FIG. 8 is a cross-sectional view of the display device according to one or more embodiments of the present disclosure.

FIG. 9 is a cross-sectional view of the display device according to one or more embodiments of the present disclosure.

FIG. 10 is a cross-sectional view of the display device according to one or more embodiments of the present disclosure.

FIG. 11 is a cross-sectional view of the display device according to one or more embodiments of the present disclosure.

FIG. 12 is a cross-sectional view of the display device according to one or more embodiments of the present disclosure.

FIG. 13A-13G are cross-sectional views illustrating a method of manufacturing a display device according to one or more embodiments of the present disclosure.

### DETAILED DESCRIPTION

In the specification, the expression that a first component (or area, layer, part, portion, etc.) is “disposed on”, “connected with” or “coupled to” a second component means that the first component is directly disposed on/connected with/coupled to the second component or means that a third component is disposed between the first component and the second component.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are only used to distinguish one component from another component. For example, without departing from the spirit and scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in the drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, the present disclosure will be described with reference to the accompanying drawings.

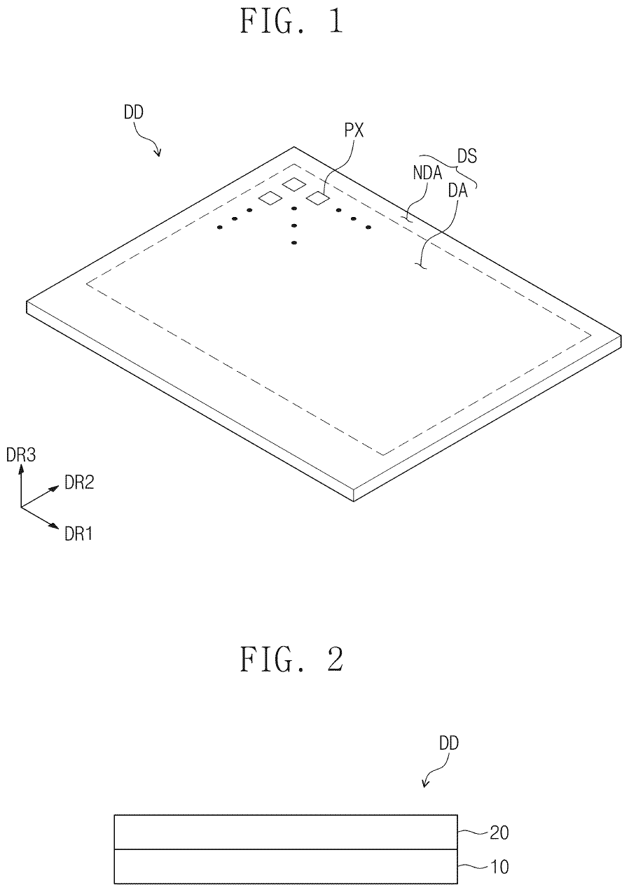

FIG. 1 is a perspective view of a display device according to one or more embodiments of the present disclosure.

Referring to FIG. 1, a display device DD according to one or more embodiments of the present disclosure may have a rectangular shape having long sides extending in a first direction DR1 and short sides extending in a second direction DR2 intersecting the first direction DR1. However, the present disclosure is not limited thereto, and the display device DD may have various shapes such as a circular shape and polygonal shapes. Hereinafter, a direction substantially perpendicular to the plane defined by the first direction DR1 and the second direction DR2 is defined as a third direction DR3. In the specification, the meaning “when viewed on a plane” (e.g., in a plan view) is defined as a state of being viewed from the third direction DR3.

An upper surface of the display device DD may be defined as a display surface DS and may have the plane defined by the first direction DR1 and the second direction DR2. Images IM generated by the display device DD may be provided to a user through the display surface DS.

The display surface DS may include a display area DA and a non-display area NDA around the display area DA along an edge or a periphery of the display area DA. The display area DA displays an image, and the non-display area NDA does not display an image. The non-display area NDA may be around (e.g., may surround) the display area DA, but the present disclosure is not limited thereto, and the non-display area NDA may not be arranged on one side of the display area DA.

A plurality of pixels PX may be arranged in the display area DA. The pixels PX may be arranged in a matrix form. Each of the pixels PX may include a pixel circuit and a light emitting diode. All of the pixels PX may generate lights having the same color. In one or more embodiments of the present disclosure, the pixels PX may also include a plurality of groups that generate lights having different colors.

FIG. 2 is a view illustrating a cross section of the display device illustrated in FIG. 1.

Referring to FIG. 2, the display device DD may include a circuit element layer 10 and a light emitting element layer 20. However, the present disclosure is not limited thereto, and in the display device DD according to one or more embodiments of the present disclosure, the light emitting element layer 20 may further include lens patterns. The lens patterns condense light emitted from the light emitting diode. A description related thereto will be made below.

The circuit element layer 10 may include a pixel circuit. The pixel circuit may control an operation of the light emitting diode of the light emitting element layer 20, which will be described below. The pixel circuit may include at least one transistor. The circuit element layer 10 may include a CMOS wafer. The CMOS wafer may include an n-type metal oxide semiconductor field effect transistor (nMOSFET)(NMOS) and a p-type MOSFET (PMOS) complementarily connected to each other. A plurality of pixel areas are regularly arranged on the CMOS wafer, and the pixel circuit is arranged in each of the pixel areas.

The light emitting element layer 20 may include a light emitting diode electrically connected to the pixel circuit. The light emitting diode is of a type of compound semiconductor and is an electric-driven light emitting diode containing gallium (Ga), phosphorus (P), and arsenic (As) as major semiconductor materials. When a forward current is applied to a p-n junction structure, electrons and holes may be coupled at a junction surface to generate a light having a specific wavelength corresponding to band gap energy.

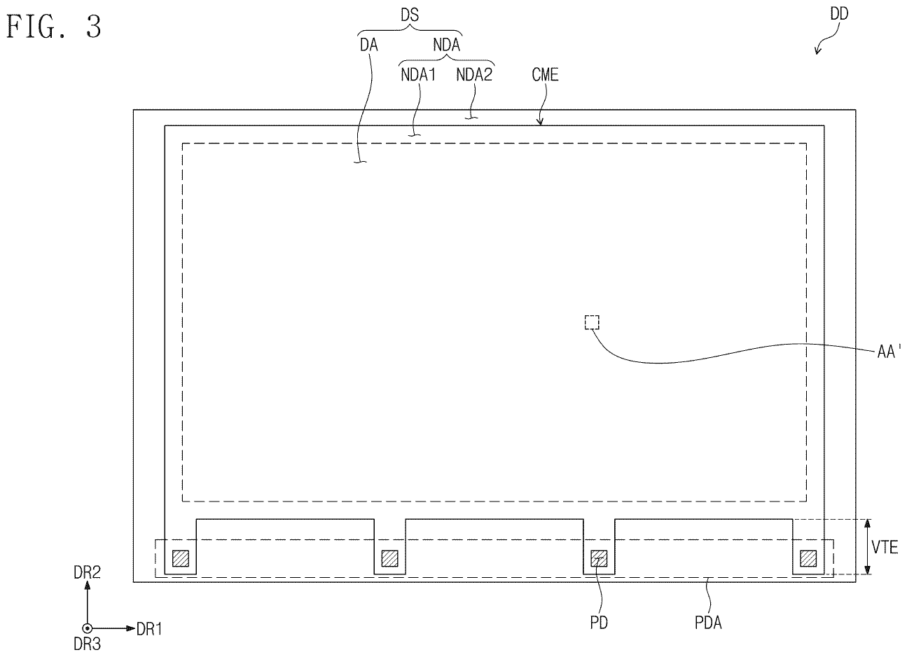

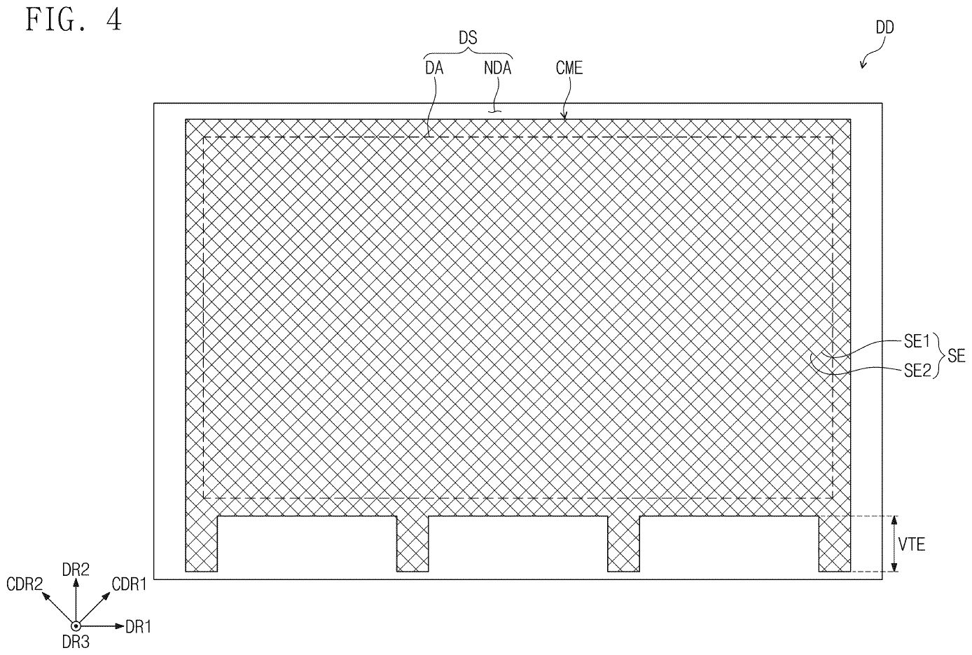

FIG. 3 is a plan view in which a common electrode is disposed in a display area and a non-display area of the display device according to one or more embodiments of the present disclosure. FIG. 4 is a plan view illustrating an arrangement relationship of a common electrode, a voltage transfer electrode, and auxiliary electrodes according to one or more embodiments of the present disclosure.

The display device DD may include the display area DA and the non-display area NDA. The non-display area NDA may be around (e.g., may surround) the display area DA. The display area DA and the non-display area NDA of the display device DD may be equally applied to the circuit element layer 10 described in FIG. 2, that is, the CMOS wafer. Hereinafter, the circuit element layer 10 is described as the CMOS wafer 10, which references the same reference numeral.

Most of a common electrode CME may be disposed in the display area DA, and an edge of the common electrode CME may be disposed in the non-display area NDA. The common electrode CME transfers a power source voltage applied from the outside to the entire display area DA.

In the specification, a portion of the non-display area NDA, which overlaps the edge of the common electrode CME, may be defined as a first non-display area NDA1, and a portion of the non-display area NDA other than the first non-display area NDA1 may be defined as a second non-display area NDA2. The second non-display area NDA2 may be an area in which the common electrode CME is not disposed.

Dummy light emitting diodes may be arranged in the first non-display area NDA1. The dummy light emitting diodes have the same stacked structure as the light emitting diode of the display area DA, are not electrically connected to the common electrode CME, and thus may not be driven (or may not emit a light).

When the light emitting diodes are formed in a specific area through the same process, an outer area may have different process conditions as compared to an inner area. For example, a thickness of a deposited metal layer may be small or an etching rate may be different. Accordingly, a defective light emitting diode may be formed in the outer area, and in consideration of this, the light emitting diode formed on the outer area is not used as an effective light emitting diode, but as the dummy light emitting diode. When the process conditions and process efficiency are consistent regardless of the areas, the dummy light emitting diode may be omitted, and thus the first non-display area NDA1 may be omitted in one or more embodiments of the present disclosure.

A plurality of driving circuits may be arranged in the second non-display area NDA2 of the CMOS wafer 10 (see FIG. 2). For example, scan drivers may be arranged in a left area and a right area of the second non-display area NDA2 with the display area DA interposed between the scan drivers. A data driver may be disposed in a partial area of the second non-display area NDA2 disposed under the display area DA. In addition, an analog circuit such as a power circuit may be disposed in a partial area of the second non-display area NDA2. The scan driver, the data driver, and the analog circuit may be embedded in the CMOS wafer. That is, the scan driver, the data driver, and the analog circuit may include transistors formed in the same manner as the pixel circuit.

A pad area PDA in which a plurality of pad electrodes PD are arranged may be disposed on one side of the second non-display area NDA2. The pad area PDA may correspond to a partial area of the second non-display area NDA2. A circuit board may be connected to the pad area PDA. FIG. 3 illustrates only four pad electrodes PD that receive the power source voltage applied to the common electrode CME, but more pad electrodes may be arranged in the pad area PDA. The pad electrodes may receive data image signals or control signals from the outside to provide the received signals to the data driver.

A voltage transfer electrode VTE may be disposed in the second non-display area NDA2. Four voltage transfer electrodes VTE corresponding to the four pad electrodes PD are illustrated. The voltage transfer electrode VTE may extend from the common electrode CME toward the pad area PDA. The voltage transfer electrode VTE may be formed through the same process as the common electrode CME, may have the same stacked structure as the common electrode CME, and may have an integral shape. The voltage transfer electrode VTE and the common electrode CME may be different portions of one electrode formed through the same process.

FIG. 4 is a plan view illustrating an arrangement relationship between the common electrode CME, the voltage transfer electrode VTE, and an auxiliary electrode SE according to one or more embodiments of the present disclosure.

The auxiliary electrode SE overlaps the common electrode CME and the voltage transfer electrode VTE. In the third direction DR3, the auxiliary electrode SE is disposed under the common electrode CME and the voltage transfer electrode VTE.

The auxiliary electrode SE may include a plurality of first auxiliary electrodes SE1 extending in a first diagonal direction CDR1 and a plurality of second auxiliary electrodes SE2 extending in a second diagonal direction CDR2. The first auxiliary electrodes SE1 are arranged along the second diagonal direction CDR2, and the second auxiliary electrodes SE2 are arranged along the first diagonal direction CDR1.

A unit area UA may be defined in an area defined by two first auxiliary electrodes SE1 closest to each other in the second diagonal direction CDR2 from among the first auxiliary electrodes SE1 and two second auxiliary electrodes SE2 closest to each other in the first diagonal direction CDR1 from among the second auxiliary electrodes SE2. According to one or more embodiments, each of the unit areas UA may have a rhombus shape on a plane (e.g., in a plan view).

However, the present disclosure is not limited thereto, and when the first auxiliary electrodes SE1 extend in the first direction DR1 and the second auxiliary electrodes SE2 extend in the second direction DR2, each of the unit areas UA may have a quadrangular shape.

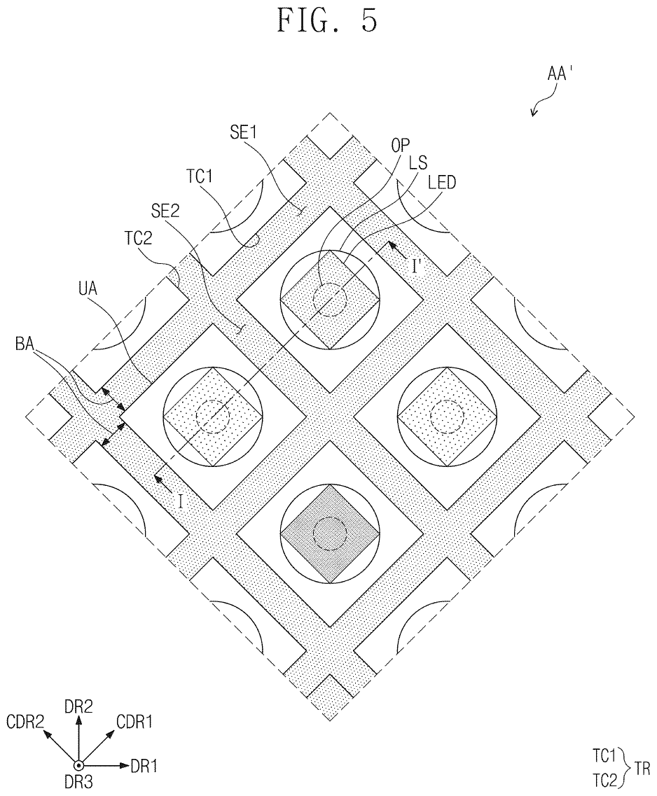

The unit areas UA are arranged inside the display area DA of FIG. 3. FIG. 5 illustrates one unit area UA. At least one light emitting diode may be disposed in the unit area UA, and a detailed description thereof will be made below.

A portion of the auxiliary electrode SE may overlap the common electrode CME, the portion overlapping the common electrode CME may be connected to the common electrode CME as a whole, and thus a voltage drop occurring in the common electrode CME may be reduced. Another portion of the auxiliary electrode SE may overlap the voltage transfer electrode VTE, the portion overlapping the voltage transfer electrode VTE may be connected to the voltage transfer electrode VTE as a whole, and thus a resistance of the voltage transfer path between the pad electrode PD (see FIG. 3) and the common electrode CME may be reduced. The auxiliary electrode SE may be formed by the same process regardless of the areas and may have an integral shape.

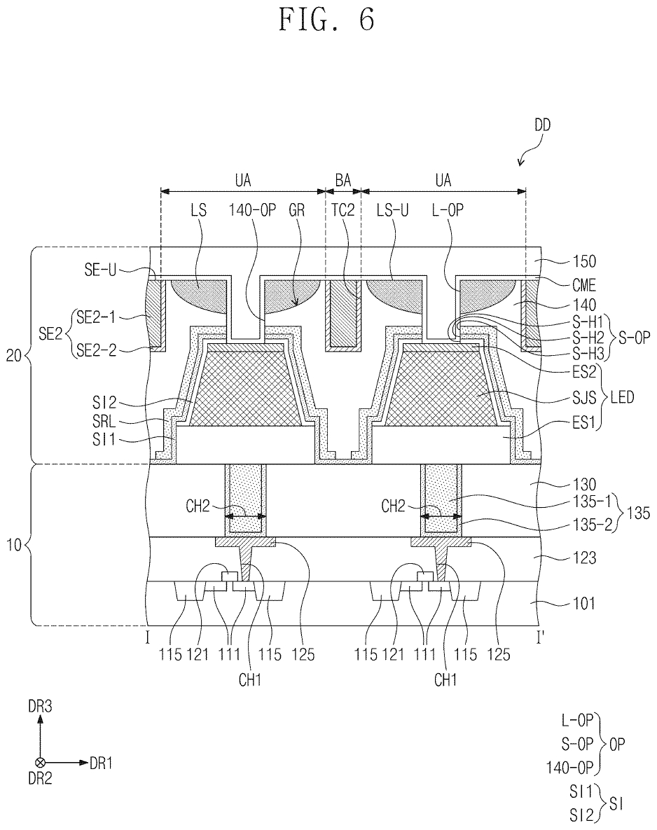

FIG. 5 is an enlarged plan view illustrating a partial area of the display area according to one or more embodiments of the present disclosure. FIG. 6 is a cross-sectional view taken along the line I-I′ of FIG. 5.

Referring to FIG. 5, the auxiliary electrode SE may include the first auxiliary electrodes SE1 and the second auxiliary electrodes SE2 crossing each other in the first and second diagonal directions CDR1 and CDR2. The auxiliary electrode SE may be disposed in a trench TR. The trench TR may include first trenches TC1 and second trenches TC2 connected to and crossing each other. The trench TR may be formed as a portion that is recessed in a direction from an upper surface to a lower surface of a flattening layer 140 (see FIG. 6), which will be described below.

The first auxiliary electrodes SE1 are disposed in the first trenches TC1, respectively, and the second auxiliary electrodes SE2 are disposed in the second trenches TC2, respectively.

The display area DA may include the plurality of unit areas UA and a boundary area BA between the unit areas UA. Each of the unit areas UA is an inner area defined by two first trenches TC1 adjacent to each other in the second diagonal direction CDR2 from among the first trenches TC1 and two second trenches TC2 adjacent to each other in the first diagonal direction CDR1 from among the second trenches TC2. The boundary area BA is an area in which the first trenches TC1 and the second trenches TC2 are located. That is, the boundary area BA may correspond to shapes of the first auxiliary electrodes SE1 and the second auxiliary electrodes SE2.

In the present embodiment, the boundary area BA is defined as an area in which the first trenches TC1 and the second trenches TC2 are arranged, but the present disclosure is not limited thereto. The plurality of unit areas UA may be defined to be narrower than that defined in FIG. 5. In this case, a width of the boundary area BA is further increased, and thus the boundary area BA may be defined to have, for example, a width greater than those of the first auxiliary electrodes SE1 and the second auxiliary electrodes SE2.

FIG. 5 illustrates light emitting diodes LED and openings OP arranged in the unit areas UA. The common electrode CME of FIG. 4 is connected to the light emitting diodes LED through the openings OP.

The light emitting diodes LED according to one or more embodiments may generate lights having different colors. For example, one of the four light emitting diodes LED may generate a red light, another thereof may generate a green light, and still another thereof may generate a blue light. The other one may generate one of a red light, a green light, a blue light, or a white light.

As an example, two first light emitting diodes LED spaced (e.g., spaced apart) from each other in the first direction DR1 may generate a green light, a second light emitting diode LED spaced (e.g., spaced apart) from a first light emitting diode LED disposed on a left side in the first diagonal direction CDR1 may generate a blue light, and a third light emitting diode LED spaced (e.g., spaced apart) from the second light emitting diode LED in the second direction DR2 and spaced (e.g., spaced apart) from the first light emitting diode LED in the second diagonal direction CDR2 may generate a red light. The first to third light emitting diodes LED may define one pixel unit, and the first to third light emitting diodes LED arranged in the one pixel unit may be arranged in a diamond shape.

Referring to FIG. 6, the display device DD may include the CMOS wafer 10 and the light emitting element layer 20.

The CMOS wafer 10 includes a silicon substrate 101. A plurality of source/drain areas 111 are defined in the silicon substrate 101. Each of the source/drain areas 111 may be an area doped with a dopant. The source/drain areas 111 may be a source of the transistor or a drain of the transistor according to a signal flow. The pair of source/drain areas 111 may define the transistor together with a gate 121, which will be described below.

Shallow trench isolation (STI) areas 115 may be further defined in the silicon substrate 101. The STI areas 115 may isolate the transistor to prevent a leakage current. The STI areas 115 may be differently arranged according to a design of the pixel circuit.

The gates 121 are arranged on the silicon substrate 101. The gates 121 may include metal. The gates 121 are arranged to correspond to the pair of source/drain areas 111, respectively. A first insulating layer 123 is disposed on the silicon substrate 101. The first insulating layer 123 may include an oxide layer such as a silicon oxide layer, a silicon nitride layer, a silicon oxy nitride layer, and/or an aluminum oxide layer. Although the single-layered first insulating layer 123 is illustrated, the first insulating layer 123 is not limited to a single-layered layer.

The CMOS wafer 10 includes a first contact electrode 125. The first contact electrode 125 may be connected to the source/drain area 111 through a first contact hole CH1 defined in the first insulating layer 123. An upper surface of the first contact electrode 125 may define the same plane (or a flat surface) as an upper surface of the first insulating layer 123. The first contact electrode 125 may be formed by a damascene method. The first contact electrode 125 may include a metal such as copper or tungsten.

A second insulating layer 130 is disposed on the first insulating layer 123. A second contact hole CH2, through which the first contact electrode 125 is exposed, may be defined in the second insulating layer 130. The second insulating layer 130 may include an oxide layer such as a silicon oxide layer, a silicon nitride layer, a silicon oxy nitride layer, and/or an aluminum oxide layer. Although the single-layered second insulating layer 130 is illustrated, the second insulating layer 130 is not limited to a single-layered layer.

A second contact electrode 135 may be disposed in the second contact hole CH2. An upper surface of the second contact electrode 135 may define the same plane (or a flat surface) as an upper surface of the second insulating layer 130. The second contact electrode 135 may include a metal structure 135-1 disposed inside the second contact hole CH2 and a barrier layer 135-2 disposed between a side surface of the metal structure 135-1 and an inner surface of the second contact hole CH2 and disposed between a lower surface of the metal structure 135-1 and an upper surface of the first contact electrode 125 exposed through the second contact hole CH2.

The metal structure 135-1 may include a metal such as copper or tungsten. The barrier layer 135-2 is also conductive. The barrier layer 135-2 may increase a coupling force for the second insulating layer 130 and the first contact electrode 125 and may prevent metal atoms of the metal structure 135-1 from being diffused into the second insulating layer 130.

The barrier layer 135-2 may include a barrier metal layer and a barrier metal nitride layer. The barrier metal nitride layer may be disposed closer to the second insulating layer 130 than the barrier metal layer. The barrier metal layer improves a coupling force, and the barrier metal nitride layer prevents diffusion of atoms in the metal structure 135-1. The barrier metal may include titanium or tantalum. The barrier layer 135-2 may include a titanium nitride layer and/or a titanium layer or may include a tantalum nitride layer and/or a tantalum layer.

In an embodiment of the present disclosure, the second contact electrode 135 may include a tungsten structure, a titanium layer surrounding a side surface and a lower surface of the tungsten structure, and a titanium nitride layer surrounding the titanium layer. In one or more embodiments of the present disclosure, the second contact electrode 135 may include a copper structure, a tantalum layer around (e.g., surrounding) a side surface and a lower surface of the copper structure, and a tantalum nitride layer around (e.g., surrounding) the tantalum layer.

According to one or more embodiments, the upper surface of the second contact electrode 135 may be concave. A first electrode part ES1, which will be described below, may be in contact with the concave upper surface of the second contact electrode 135. The concave upper surface of the second contact electrode 135 may be formed by a damascene method. In the damascene method, in a chemical mechanical polishing (CMP) process, the second contact electrode 135 is further polished than the second insulating layer 130, and thus a dishing phenomenon may occur in the second contact electrode 135.

The light emitting diode LED is disposed on the second insulating layer 130. The light emitting diodes LED according to one or more embodiments may generate lights having different colors. However, the present disclosure is not limited thereto, and the light emitting diodes LED may generate lights having the same color.

The light emitting diode LED may include a first electrode, a second electrode, and a light emitting layer disposed between the first electrode and the second electrode. In the present embodiment, the first electrode is described as the first electrode part ES1, and the second electrode is described as a second electrode part ES2. Further, the light emitting layer includes a semiconductor junction structure SJS.

The light emitting diode LED according to the present embodiment may include the first electrode part ES1, the semiconductor junction structure SJS disposed on the first electrode part ES1, and the second electrode part ES2 disposed on the semiconductor junction structure SJS.

The first electrode part ES1 may be in contact with the second contact electrode 135 and may have a width greater than that of the semiconductor junction structure SJS on a cross section. The second electrode part ES2 may cover an upper surface of the semiconductor junction structure SJS. However, the present disclosure is not limited thereto, and the second electrode part ES2 may cover at least a portion of an upper surface and a side surface of the semiconductor junction structure SJS.

In the present embodiment, the first electrode part ES1 is described as an anode (or an anode structure), and the second electrode part ES2 is described as a cathode (or a cathode structure), but the present disclosure is not limited thereto. In one or more embodiments of the present disclosure, the first electrode part ES1 may be a cathode, and the second electrode part ES2 may be an anode. A stacked structure of the semiconductor junction structure SJS may be changed depending on whether the first electrode part ES1 is an anode or a cathode.

The light emitting element layer 20 may include a side insulating layer SI disposed on a side surface of the first electrode part ES1, a side surface of the semiconductor junction structure SJS, a side surface of the second electrode part ES2, and an upper surface of the second electrode part ES2. A first opening S-OP, through which a portion of the upper surface of the second electrode part ES2 is exposed, may be defined in the side insulating layer SI.

The light emitting element layer 20 may include a first side insulating layer SI1 disposed adjacent to a side surface of the light emitting diode LED. The first side insulating layer SI1 may be around (e.g., may surround) the light emitting diode LED.

The first side insulating layer SI1 may be a common layer that is commonly provided on the adjacent light emitting diodes LEDs in the unit areas UA and on the second insulating layer 130 in the boundary areas BA.

The first side insulating layer SI1 may prevent contact between the light emitting diode LED and a side reflective layer SRL. For example, the first side insulating layer SI1 may include at least one of a silicon oxide, a silicon nitride, a silicon oxy nitride, an aluminum oxide, a zirconium oxide, a hafnium oxide, and/or a titanium oxide.

The side reflective layer SRL may be disposed outside the first side insulating layer SI1. The side reflective layer SRL may increase light efficiency by reflecting a light generated by the light emitting diode LED so that the light generated by the light emitting diode LED is emitted to the first opening S-OP. The side reflective layer SRL may include gold (Au), copper (Cu), silver (Ag), titanium (Ti), and/or aluminum (Al).

For example, the side reflective layer SRL may be provided as a plurality of side reflective layers SRL. The side reflective layers SRL may each cover the overlapping light emitting diode LED and may be spaced (e.g., spaced apart) from each other. The side reflective layers SRL may be separated from and spaced (e.g., spaced apart) from the boundary area BA. However, the present disclosure is not limited thereto, and the side reflective layer SRL may have an integral shape.

The light emitting element layer 20 may further include a second side insulating layer SI2 disposed inside the first side insulating layer SI1. The second side insulating layer SI2 may protect a partial area of the side surface of the light emitting diode LED during a process of manufacturing the light emitting diode LED (e.g., the second side insulating layer SI2 may be disposed around outer peripheral surfaces of the semiconductor junction structure SJS and the second electrode part ES2). The second side insulating layer SI2 may include a single layer or a plurality of layers. The second side insulating layer SI2 may include a silicon oxide, a silicon nitride, a silicon oxy nitride, an aluminum oxide, a zirconium oxide, a hafnium oxide, and/or a titanium oxide.

The first opening S-OP may correspond to a light emitting area of the light emitting diode LED. As illustrated in FIG. 6, the first opening S-OP corresponding to the light emitting area of the light emitting diode LED may have a rhombus shape on a plane. However, a shape of the corresponding first opening S-OP on a plane (e.g., in a plan view) is not limited to any one particular shape. The first opening S-OP may correspond to a passage through which the common electrode CME is connected to the second electrode part ES2.

The first opening S-OP may include a (1-1)^{th} opening S-H1 defined in the second side insulating layer SI2, a (1-2)^{th} opening S-H2 defined in the first side insulating layer SI1, and a (1-3)^{th} opening S-H3 defined in the side reflective layer SRL. The (1-1)^{th} opening S-H1, the (1-2)^{th} opening S-H2, and the (1-3)^{th} opening S-H3 may be aligned with each other to expose a portion of the upper surface of the second electrode part ES2.

The flattening layer 140 may be disposed on the second insulating layer 130. The flattening layer 140 may overlap the plurality of unit areas UA and the boundary area BA and may be disposed on the plurality of light emitting diodes LED. The flattening layer 140 may be disposed to fill an area in which the light emitting diodes LED are not arranged. According to one or more embodiments of the present disclosure, the flattening layer 140 may include an inorganic material.

The flattening layer 140 may be in contact with the side reflective layer SRL. A second opening 140-OP overlapping the first opening S-OP may be defined in the flattening layer 140. According to one or more embodiments, an area of the first opening S-OP and an area of the second opening 140-OP may be different from each other. A shape of the first opening S-OP and a shape of the second opening 140-OP may be the same on a plane (e.g., in a plan view).

The first and second trenches TC1 and TC2 (see FIG. 5) may be defined in the flattening layer 140 overlapping the boundary area BA. FIG. 6 illustrates, as an example, the second trenches TC2. The second auxiliary electrodes SE2 may be arranged in the second trenches TC2. The first auxiliary electrodes SE1 illustrated in FIG. 5 may be formed by the same process as the second auxiliary electrodes SE2, and a description related to the second auxiliary electrodes SE2 may be equally applied to the first auxiliary electrodes SE1.

Similar to the second contact electrode 135, the second auxiliary electrode SE2 may be formed by the damascene method, and an upper surface of the second auxiliary electrode SE2 may be concave. The second auxiliary electrode SE2 may include a metal structure SE2-1 disposed inside the second trench TC2 and a barrier layer SE2-2 disposed between the metal structure SE2-1 and the second trench TC2. The metal structure SE2-1 may include a metal such as copper and/or tungsten. The metal structure SE2-1 and the barrier layer SE2-2 may be conductive. The barrier layer SE2-2 may increase a coupling force of the second auxiliary electrode SE2 with respect to the flattening layer 140 and prevent metal atoms of the metal structure SE2-1 from being diffused into the flattening layer 140.

The barrier layer SE2-2 may include a barrier metal layer and a barrier metal nitride layer. The barrier metal nitride layer may be disposed closer to the flattening layer 140 than the barrier metal layer. The barrier metal layer may include titanium or tantalum. The barrier metal nitride layer may include a titanium nitride layer and/or a tantalum nitride layer.

Grooves GR recessed in a direction from an upper surface of the flattening layer 140 toward the light emitting diodes LED may be defined in the flattening layer 140 overlapping the unit areas UA. The grooves GR may be formed in the CMP process that forms the second auxiliary electrodes SE2. An inner space defined by each of the grooves GR may have a semi-elliptical shape or a downward concave shape. The second opening 140-OP may overlap the groove GR.

According to the present embodiment, the light emitting element layer 20 may include lens patterns LS arranged on the flattening layer 140. Each of the lens patterns LS may be disposed inside the corresponding groove GR. The lens patterns LS may condense lights generated by the light emitting diodes LED. According to one or more embodiments, an upper surface LS-U of the lens pattern LS may define the same plane as an upper surface SE-U of the second auxiliary electrode SE2.

The lens patterns LS may include a silicon nitride. In this case, the flattening layer 140 may include a silicon oxide. A refractive index of the flattening layer 140 may be greater than a refractive index of the lens patterns LS. For example, the flattening layer 140 may have a refractive index of 1.5 to 1.6, and the lens patterns LS may have a refractive index of 1.4 to 1.5. According to the present embodiment, the lens patterns LS may have a relatively higher density than that of the flattening layer 140. The lens patterns LS may include a refractive index lower than that of the flattening layer 140 and thus efficiently condense lights generated by the light emitting diodes LED.

Each of the lens patterns LS may have a shape corresponding to a shape of the inner space of the groove GR. In the present embodiment, the lens patterns LS may have a semi-elliptical shape or a downward concave shape.

A third opening L-OP overlapping the first and second openings S-OP and 140-OP may be defined in each of the lens patterns LS. The first and second openings S-OP and 140-OP and the third opening L-OP may define the opening OP, and the opening OP may expose a portion of the upper surface of the second electrode part ES2. A shape of the third opening L-OP on a plane (e.g., in a plan view) may correspond to shapes of the first and second openings S-OP and 140-OP.

The common electrode CME is disposed on the flattening layer 140. The common electrode CME may overlap the unit areas UA and the boundary area BA. The common electrode CME may include a transparent conductive material to emit a light generated by the light emitting diode LED. The common electrode CME may include a transparent conductive oxide such as an indium tin oxide (ITO), an indium zinc oxide (IZO), a zinc oxide (ZnO), a zinc tin oxide (ZTO), and/or an indium gallium zinc oxide (IGZO). In the present embodiment, the common electrode CME may be in contact with the second auxiliary electrodes SE2 in the boundary area BA and may be connected to the second electrode part ES2 through the opening OP in the unit areas UA.

The common electrode CME may be in contact with the upper surface SE-U of the second auxiliary electrode SE2 in the boundary area BA, and the common electrode CME may be in contact with the upper surfaces LS-U of the lens patterns LS and side surfaces of the lens patterns LS which define the openings OP, a side surface of the flattening layer 140, a side surface of the first side insulating layer SI1, a side surface of the side reflective layer SRL, and a side surface of the second side insulating layer SI2, in the unit areas UA.

The power source voltage applied through the common electrode CME may be transferred to the light emitting diode LED. FIG. 6 illustrates, as an example, the common electrode CME connected to two light emitting diodes LED. One of the two light emitting diodes LED may be defined as the first light emitting diode LED, and the other one thereof may be defined as a second light emitting diode LED.

According to one or more embodiments of the present disclosure, because the upper surfaces SE-U of the second auxiliary electrodes SE2 are in contact with the common electrode CME in a longitudinal direction of the second trench TC2, the common electrode CME and the second auxiliary electrodes SE2 may ensure a sufficient contact area.

According to the present embodiment, the lens patterns LS may be arranged inside the grooves GR defined in the flattening layer 140 and covered by the common electrode CME.

A passivation layer 150 may be disposed on the common electrode CME.

The passivation layer 150 may be disposed in the display area DA and the non-display area NDA of FIG. 3 to protect the common electrode CME and the voltage transfer electrodes VTE. In the present embodiment, the passivation layer 150 may include an organic material and/or an inorganic material.

The passivation layer 150 may compensate for a step formed by components arranged under the passivation layer 150. Thus, an upper surface of the passivation layer 150 may provide a flat surface.

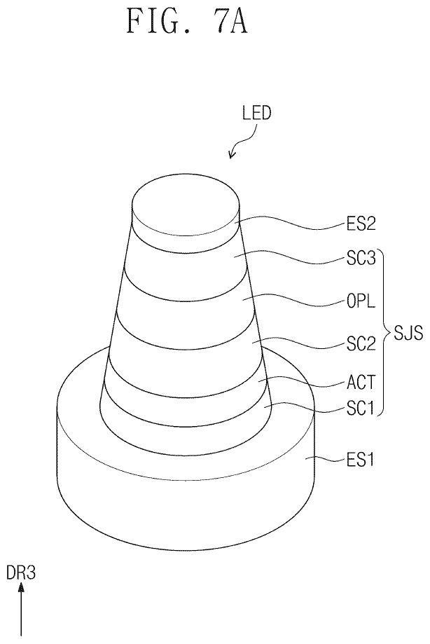

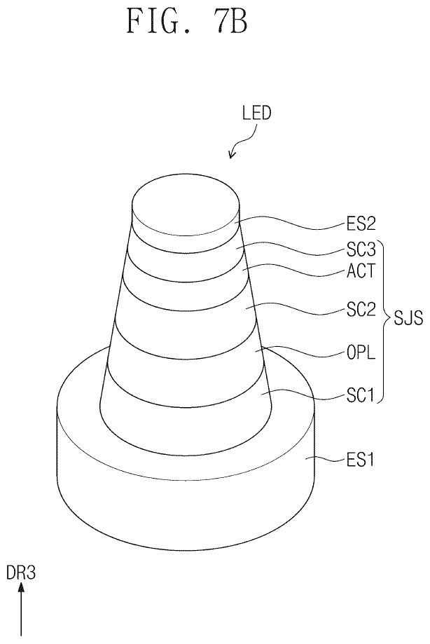

FIG. 7A is a perspective view of a light emitting diode according to one or more embodiments of the present disclosure. FIG. 7B is a perspective view of the light emitting diode according to one or more embodiments of the present disclosure. The light emitting diode LED may include the first electrode part ES1, the semiconductor junction structure SJS, and the second electrode part ES2.

Referring to FIGS. 7A and 7B, the light emitting diode LED may have a column shape. The light emitting diode LED may have a size of a nanoscale to a micrometer scale. The light emitting diode LED may have a diameter (or a width) and/or a length in a range of a nano scale to a micro scale. The diameter (or the width) may mean a diameter (a width) in one direction perpendicular to the third direction DR3 (thickness direction), and the length may mean a length in the third direction DR3.

However, the size of the light emitting diode LED is not limited thereto, and the size of the light emitting diode LED may be variously changed according to design conditions of various devices using a light emitting device using the light emitting diode LED as a light source.

In more detail, in the light emitting diode LED, the semiconductor junction structure SJS may have a truncated cone shape. In one or more embodiments, the semiconductor junction structure SJS may include a first semiconductor layer SC1, a second semiconductor layer SC2 disposed on the first semiconductor layer SC1, a third semiconductor layer SC3 disposed on the second semiconductor layer SC2, an optical layer OPL, and an active layer ACT.

The semiconductor junction structure SJS of the light emitting diode LED may be formed by a dry etching process and manufactured in a truncated cone shape. In the semiconductor junction structure SJS having a truncated cone shape, diameters of the first to third semiconductor layers SC1, SC2, and SC3, the optical layer OPL, and the active layer ACT may be different from each other. The diameter may mean an average width in the one direction perpendicular to the third direction DR3.

The optical layer OPL and the active layer ACT may be spaced (e.g., spaced apart) from each other in the third direction DR3. One of the optical layer OPL or the active layer ACT may be disposed between the first semiconductor layer SC1 and the second semiconductor layer SC2, and the other one thereof may be disposed between the second semiconductor layer SC2 and the third semiconductor layer SC3.

Each of the first to third semiconductor layers SC1, SC2, and SC3 may include an N-type semiconductor layer or a P-type semiconductor layer. One of the first to third semiconductor layers SC1, SC2, and SC3 may be a P-type semiconductor layer, and the other two thereof may be n-type semiconductor layers. For example, the N-type semiconductor layer may include at least one semiconductor material from among InAlGaN, GaN, AlGaN, InGaN, AlN, or InN, and may be doped with a first conductive dopant such as silicon (Si), germanium (Ge), or tin (Sn).

The P-type semiconductor layer may include at least one semiconductor material from among InAlGaN, GaN, AlGaN, InGaN, AlN, or InN and may be doped with a second conductive dopant such as magnesium (Mg), zinc (Zn), calcium (Ca), or barium (Ba). However, this is an example, and materials constituting the N-type semiconductor layer and the P-type semiconductor layer are not limited thereto.

Referring to FIG. 7A, the optical layer OPL may be disposed between the second semiconductor layer SC2 and the third semiconductor layer SC3, and the active layer ACT may be disposed between the first semiconductor layer SC1 and the second semiconductor layer SC2. In this case, each of the second semiconductor layer SC2 and the third semiconductor layer SC3 may include the N-type semiconductor layer, and the first semiconductor layer SC1 may include the P-type semiconductor layer.

The second semiconductor layer SC2 and the third semiconductor layer SC3 spaced (e.g., spaced apart) from each other with the optical layer OPL interposed between the second semiconductor layer SC2 and the third semiconductor layer SC3 may include an N-type semiconductor layer. Dopant concentrations in the second semiconductor layer SC2 and the third semiconductor layer SC3 may be different from each other. For example, the dopant concentration at which the second semiconductor layer SC2 is doped may be greater than the dopant concentration at which the third semiconductor layer SC3 is doped. Unlike this, the dopant concentrations in the second semiconductor layer SC2 and the third semiconductor layer SC3 may be the same.

Referring to FIG. 7B, the optical layer OPL may be disposed between the first semiconductor layer SC1 and the second semiconductor layer SC2, and the active layer ACT may be disposed between the second semiconductor layer SC2 and the third semiconductor layer SC3. In this case, each of the first semiconductor layer SC1 and the second semiconductor layer SC2 may include the N-type semiconductor layer, and the third semiconductor layer SC3 may include the P-type semiconductor layer.

The first semiconductor layer SC1 and the second semiconductor layer SC2 spaced (e.g., spaced apart) from each other with the optical layer OPL interposed between the first semiconductor layer SC1 and the second semiconductor layer SC2 may include an N-type semiconductor layer. Dopant concentrations in the first semiconductor layer SC1 and the second semiconductor layer SC2 may be different from each other.

The active layer ACT may be formed in a single-quantum well structure or a multi-quantum well structure. The active layer ACT may emit a light by coupling between electrons and holes according to an electric signal applied through the P-type semiconductor layer and the N-type semiconductor layer. The active layer ACT may emit a light in a wavelength range of 400 nm to 900 nm and may use a double hetero-structure.

For example, the active layer ACT may have a structure in which a semiconductor material having high band gap energy and a semiconductor material having low band gap energy are alternately stacked. Further, the active layer ACT may include Group III to V semiconductor materials selected according to the wavelength band of the emitted light. In the specification, “Group” means a group of the IUPAC Periodic Table.

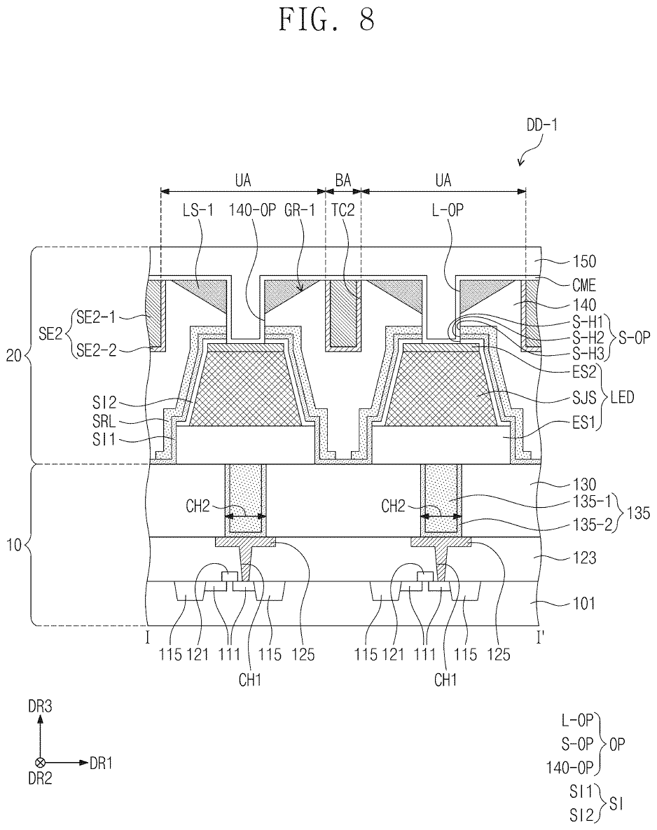

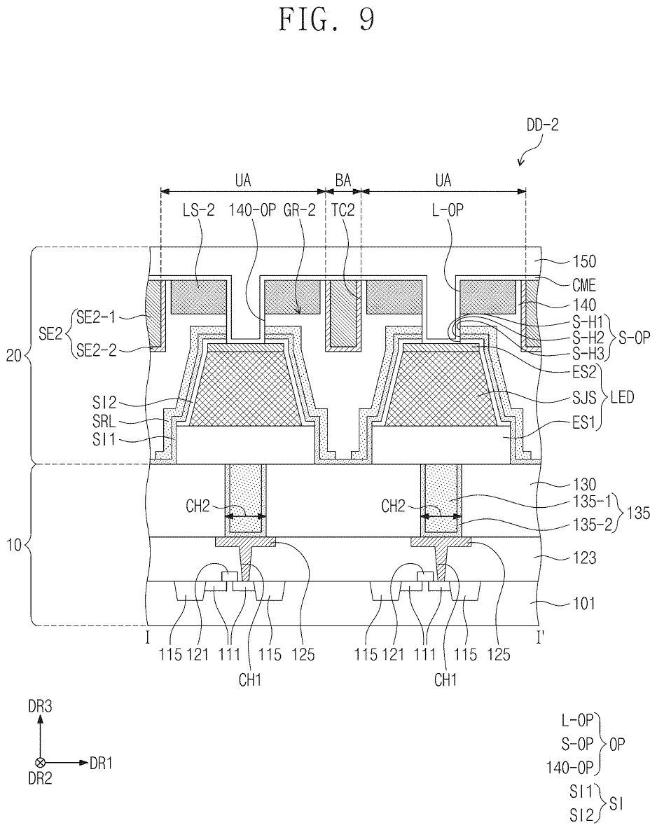

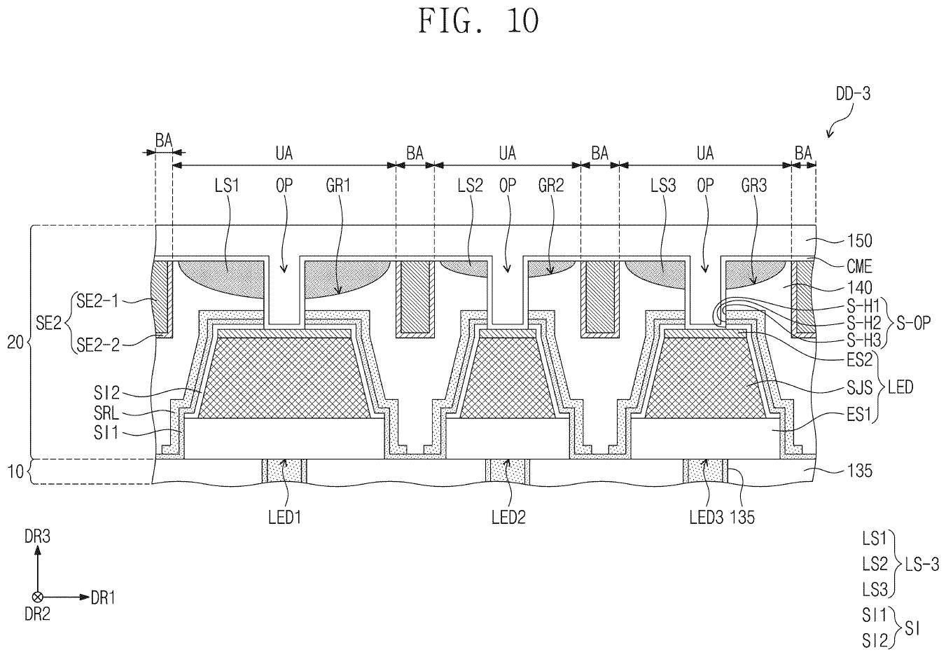

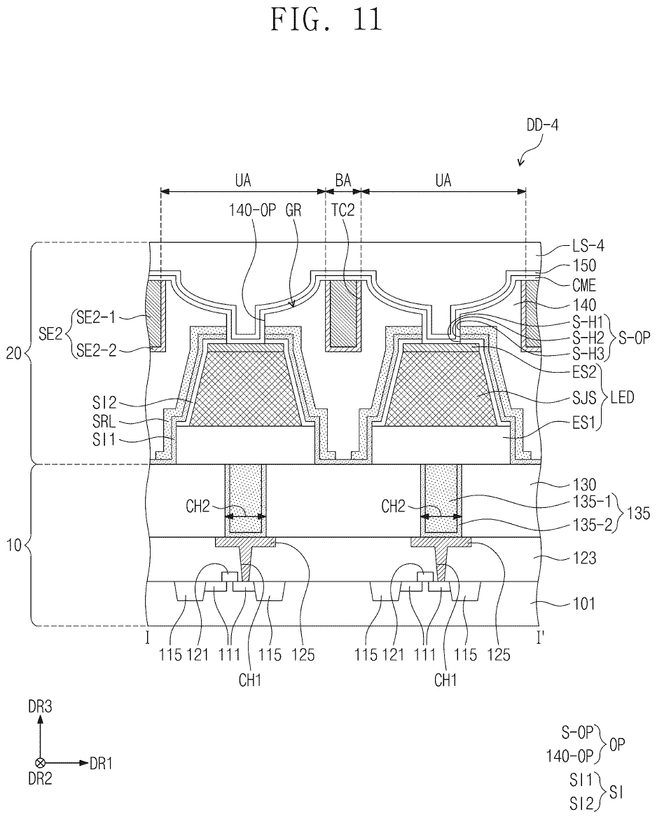

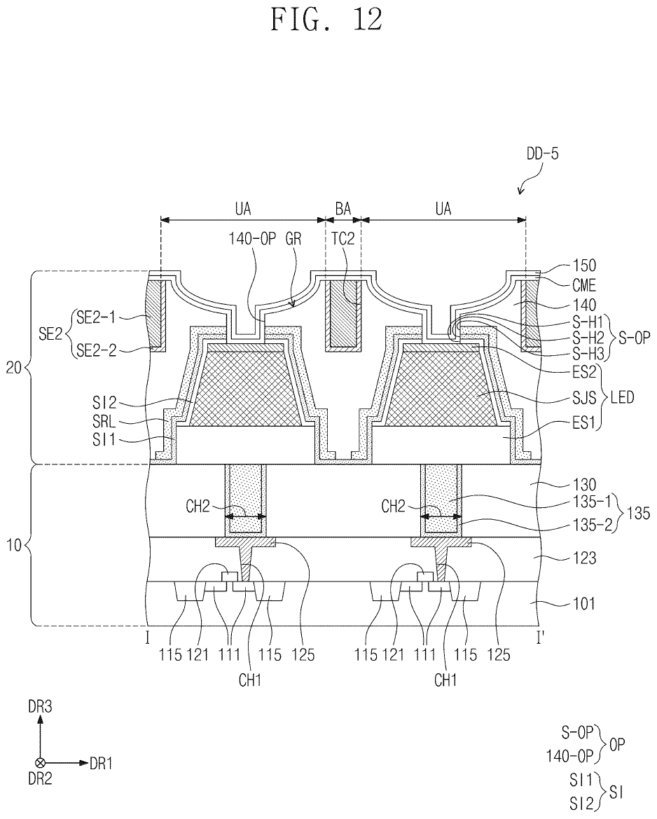

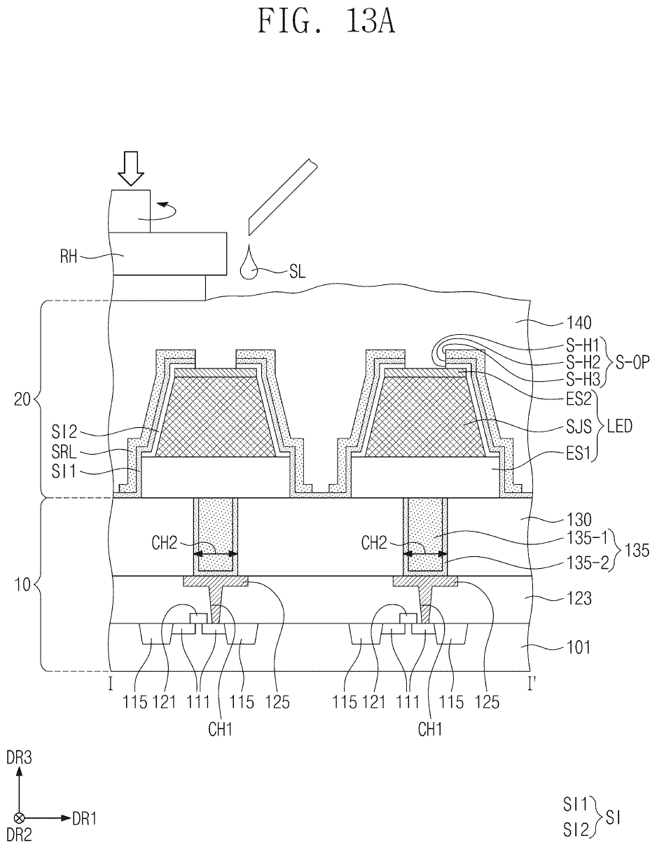

FIG. 8 is a cross-sectional view of the display device according to one or more embodiments of the present disclosure. FIG. 9 is a cross-sectional view of the display device according to one or more embodiments of the present disclosure. FIG. 10 is a cross-sectional view of the display device according to one or more embodiments of the present disclosure. FIG. 11 is a cross-sectional view of the display device according to one or more embodiments of the present disclosure. FIG. 12 is a cross-sectional view of the display device according to one or more embodiments of the present disclosure. The same/similar reference numerals are assigned to the same/similar configurations as those described in FIG. 1-7B.

The following description may be commonly applied to FIG. 8-12. The display device according to one or more embodiments may include the CMOS wafer 10 and the light emitting element layer 20. The CMOS wafer 10 may include the silicon substrate 101, the first insulating layer 123, and the second insulating layer 130. The light emitting diode LED is disposed on the second insulating layer 130. The flattening layer 140 is disposed on the second insulating layer 130 and covers the light emitting diode LED.

The side reflective layer SRL and the side insulating layer SI including first and second side insulating layers SI1 and SI2 may be included between the flattening layer 140 and the light emitting diode LED. The second auxiliary electrodes SE2 may be arranged in the flattening layer 140 overlapping the boundary area BA. The common electrode CME may be disposed on the flattening layer 140. Hereinafter, differences between embodiments related to the display device illustrated in FIG. 8-12 will be mainly described.

Referring to FIG. 8, grooves GR-1 recessed in a direction from the upper surface of the flattening layer 140 toward the light emitting diodes LED may be defined in the flattening layer 140 included in a display device DD-1 according to one or more embodiments. According to the present embodiment, an inner space defined by each of the grooves GR-1 may have a triangular shape.

Each of the lens patterns LS-1 may be disposed in a corresponding groove GR-1. Each of the lens patterns LS-1 may have a shape corresponding to a shape of the inner space of the groove GR-1. In the present embodiment, the lens patterns LS-1 may have a triangular shape.

Referring to FIG. 9, grooves GR-2 recessed in a direction from the upper surface of the flattening layer 140 toward the light emitting diodes LED may be defined in the flattening layer 140 included in a display device DD-2 according to one or more embodiments. According to the present embodiment, an inner space defined by each of the grooves GR-2 may have a triangular shape.

Each of the lens patterns LS-2 may be disposed in a corresponding groove GR-2. Each of the lens patterns LS-2 may have a shape corresponding to a shape of the inner space of the groove GR-2. In the present embodiment, the lens patterns LS-2 may have a quadrangular shape.

Referring to FIG. 10, a display device DD-3 according to one or more embodiments may include first to third light emitting diodes LED1, LED2, and LED3 having different areas.

The first to third light emitting diodes LED1, LED2, and LED3 may generate light having different colors. For example, the first light emitting diode LED1 may generate a red light, the second light emitting diode LED2 may generate a green light, and the third light emitting diode LED3 may generate a blue light.

The first to third light emitting diodes LED1, LED2, and LED3 may have different areas/widths. For example, the area of the first light emitting diode LED1 may be the largest, and the area of the second light emitting diode LED2 may be the smallest.

First to third grooves GR1, GR2, and GR3 may be defined in the flattening layer 140 overlapping the unit areas UA. The first to third grooves GR1, GR2, and GR3 may have shapes recessed in a direction from the upper surface of the flattening layer 140 toward the first to third light emitting diodes LED1, LED2, and LED3. Each of the first to third grooves GR1, GR2, and GR3 may have a semi-elliptical shape.

The first groove GR1 may overlap the first light emitting diode LED1, the second groove GR2 may overlap the second light emitting diode LED2, and the third groove GR3 may overlap the third light emitting diode LED3.

According to the present embodiment, areas of inner spaces defined by the first to third grooves GR1, GR2, and GR3 may be different from each other. The area of the inner space defined by the third groove GR3 may be smaller than the area of the inner space defined by the first groove GR1 and greater than the area of the inner space defined by the second groove GR2.

The lens patterns LS-3 may include a first pattern LS1, a second pattern LS2, and a third pattern LS3. The first pattern LS1 may be disposed inside the first groove GR1, the second pattern LS2 may be disposed inside the second groove GR2, and the third pattern LS3 may be disposed inside the third groove GR3.

The first to third patterns LS1, LS2, and LS3 may have shapes corresponding to shapes of the inner spaces of the first to third grooves GR1, GR2, and GR3. In the present embodiment, the first to third patterns LS1, LS2, and LS3 may have a semi-elliptical shape or a downward concave shape.

Referring to FIG. 11, a display device DD-4 according to one or more embodiments may further include a lens layer LS-4 disposed on the passivation layer 150.

According to the present embodiment, the common electrode CME may be in contact with the second auxiliary electrode SE2 in the boundary area BA and may be disposed in the grooves GR in the unit areas UA to be in contact with the flattening layer 140.

The passivation layer 150 may be disposed on the common electrode CME and have a shape corresponding to a shape of the common electrode CME. Unlike the passivation layer 150 described in FIG. 6, the passivation layer 150 according to the present embodiment may not provide a flat surface.

The lens layer LS-4 may be disposed on the passivation layer 150. The lens layer LS-4 may overlap the boundary area BA and the unit areas UA. That is, the lens layer LS-4 may be disposed on the passivation layer 150 in an integral pattern.

According to the present embodiment, a refractive index of the lens layer LS-4 may be smaller than the refractive index of the flattening layer 140. For example, the refractive index of the lens layer LS-4 may be in a range of 1.4 to 1.5, and the refractive index of the flattening layer 140 may be in a range of 1.5 to 1.6. The flattening layer 140 may include a silicon oxide, and the lens layer LS-4 may include an organic material and hollow silica mixed with the organic material.

According to the present embodiment, a refractive index of the passivation layer 150 may be equal to or lower than the refractive index of the flattening layer 140.

Referring to FIG. 12, the common electrode CME of a display device DD-5 according to one or more embodiments may be in contact with the second auxiliary electrode SE2 in the boundary area BA and may be disposed in the grooves GR in the unit areas UA to be in contact with the flattening layer 140.

The passivation layer 150 may be disposed on the common electrode CME and may have a shape corresponding to a shape of the common electrode CME.

Unlike the passivation layer 150 described in FIG. 6, the passivation layer 150 according to the present embodiment may not provide a flat surface.

According to the present embodiment, the refractive index of the flattening layer 140 may be greater than the refractive index of the passivation layer 150. For example, the refractive index of the passivation layer 150 may be in a range of 1.4 to 1.5, and the refractive index of the flattening layer 140 may be in a range of 1.5 to 1.6. The flattening layer 140 may include a silicon oxide, and the passivation layer 150 may include a silicon nitride. In one or more embodiments, for example, as shown in FIG. 12, a lens layer LS may be omitted.

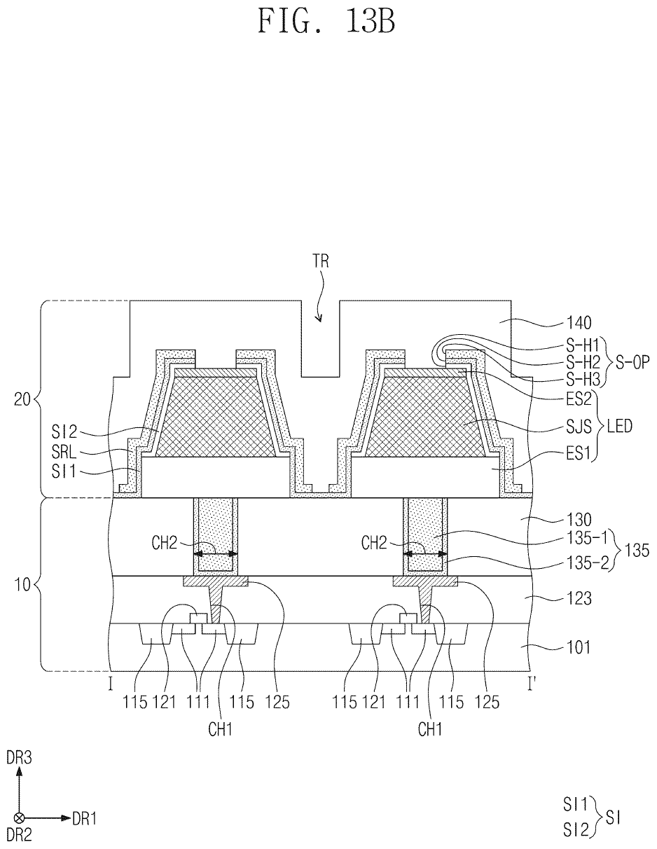

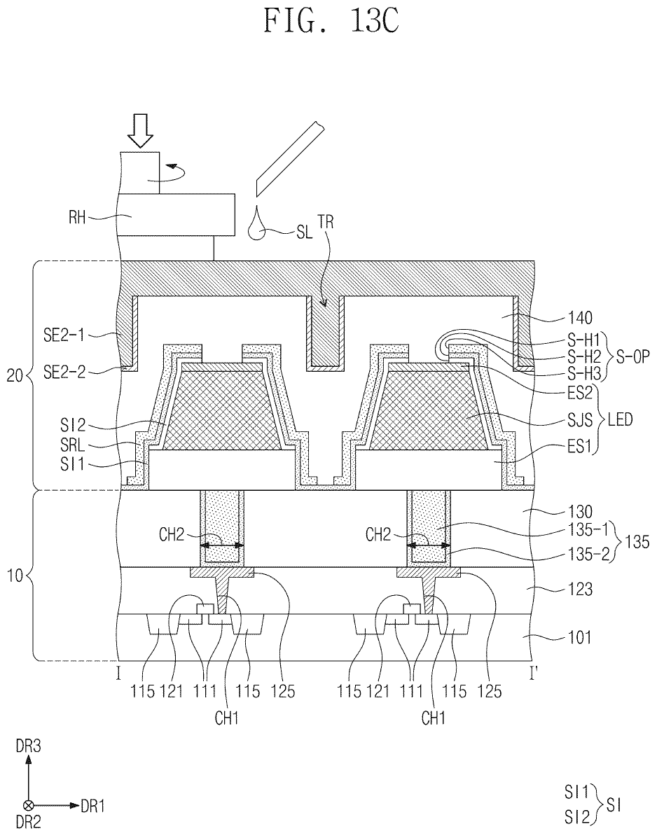

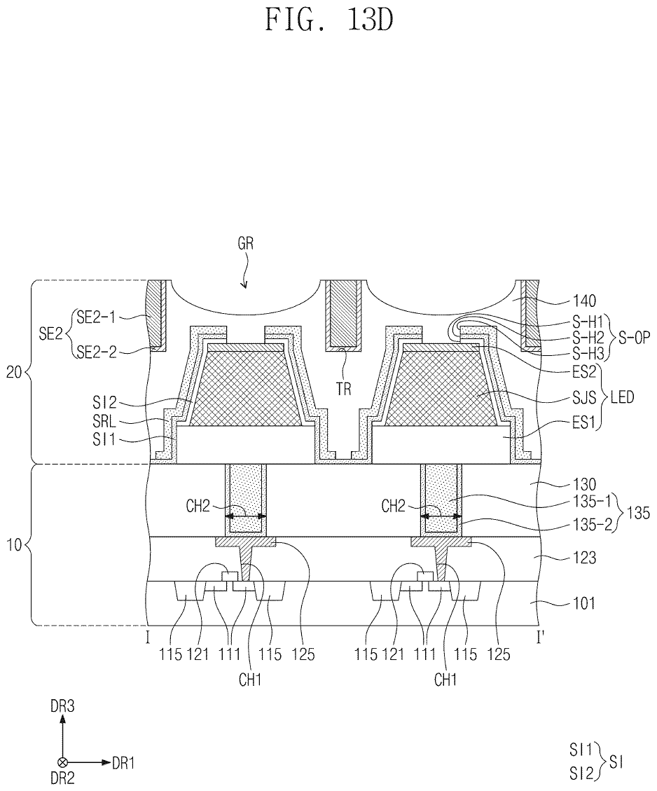

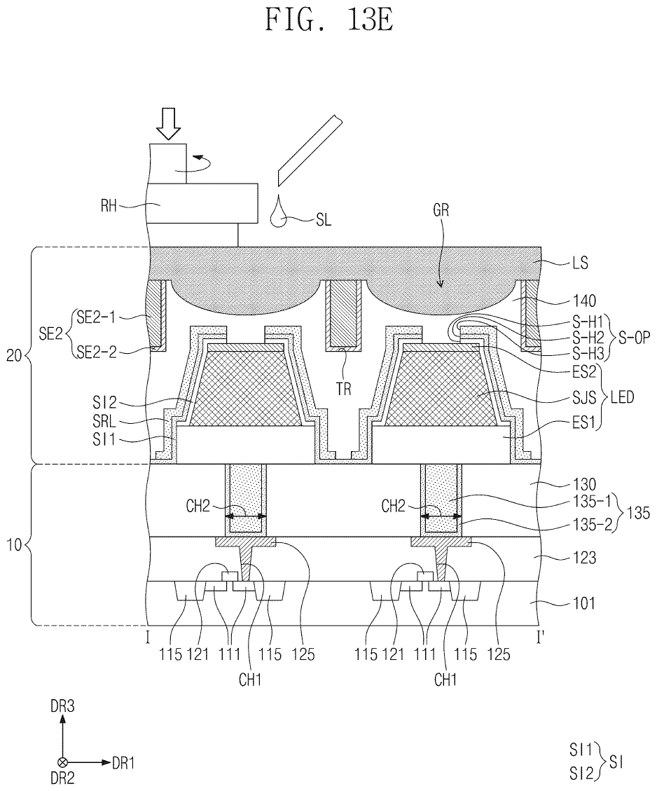

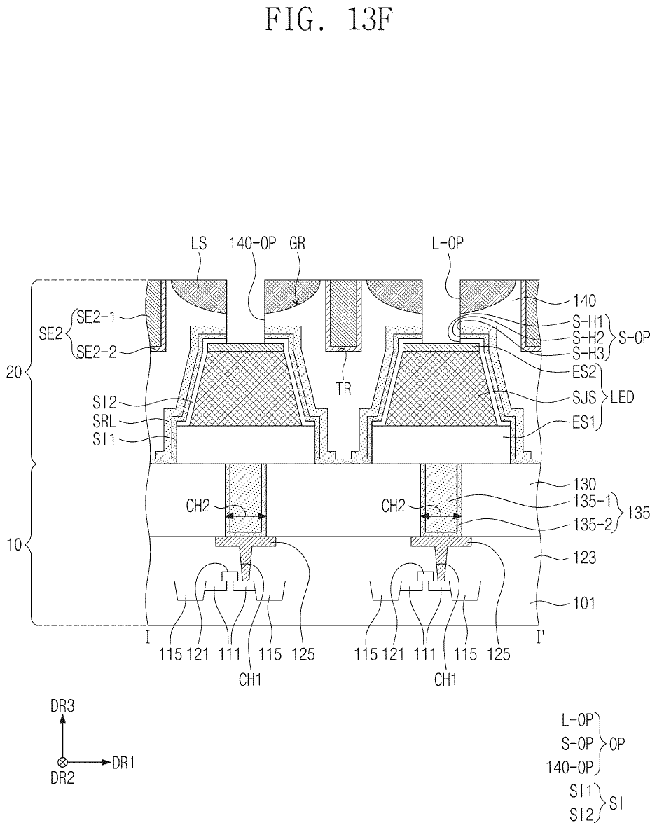

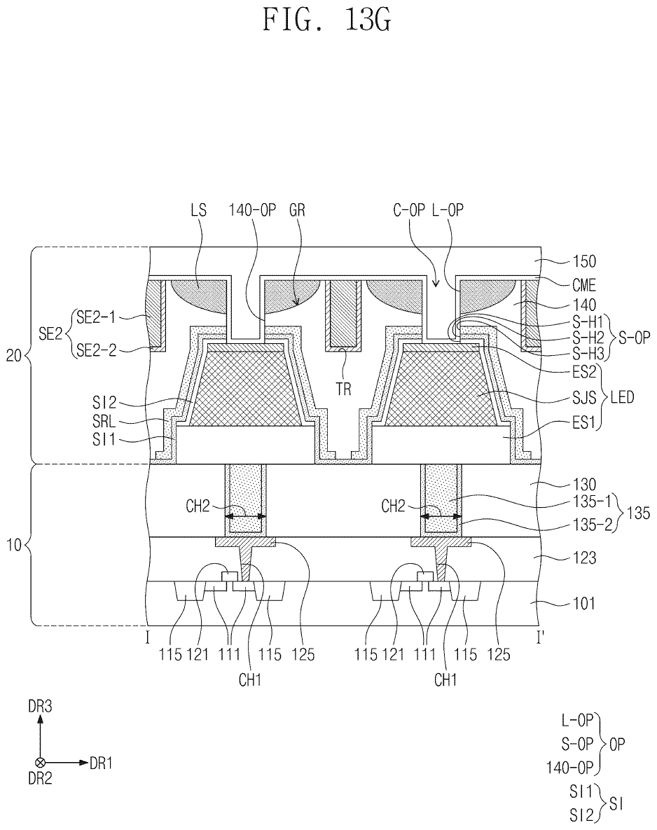

FIG. 13A-13G are cross-sectional views illustrating a method of manufacturing a display device according to one or more embodiments of the present disclosure. The same/similar reference numerals are used for the same/similar components as those described in FIG. 1-7B, and duplicated descriptions thereof will be omitted.

Referring to FIG. 13A, a method of manufacturing a display device according to the present embodiment may include an operation of providing a CMOS wafer. The CMOS wafer may be provided to include the silicon substrate 101, the first insulating layer 123, and the second insulating layer 130.

The source/drain area 111 and the STI areas 115 may be formed in the silicon substrate 101. The gates 121 may be formed on the silicon substrate 101. The first contact hole CH1 may be formed in the first insulating layer 123, and the first contact electrode 125 may be formed inside the first contact hole CH1 and connected to the source/drain area 111 through the first contact hole CH1.

The second contact hole CH2 may be formed in the second insulating layer 130. The second contact hole CH2 may expose the first contact electrode 125. The second contact electrode 135 may be formed in the second contact hole CH2. The second contact electrode 135 may include the metal structure 135-1 disposed inside the second contact hole and the barrier layer 135-2 disposed between the side surface of the metal structure 135-1 and the inner surface of the second contact hole CH2 and disposed between the lower surface of the metal structure 135-1 and the upper surface of the first contact electrode 125 exposed through the second contact hole CH2.

Thereafter, the method may include an operation of forming the light emitting diodes LED by forming and patterning a conductive layer on the second insulating layer 130.

Each of the light emitting diodes LED may include the first electrode part ES1 connected to the second contact electrode 135, the semiconductor junction structure SJS formed on the first electrode part ES1, and the second electrode part ES2 formed on the semiconductor junction structure SJS.

Thereafter, the side insulating layer SI covering the light emitting diodes LED may be formed. The side insulating layer SI may include the first side insulating layer SI1 adjacent to the side surface of the light emitting diode LED and the second side insulating layers SI2 arranged between the first side insulating layer SI1 and the light emitting diode LED and covering the light emitting diodes LED. The first and second side insulating layers SI1 and SI2 may include a silicon oxide layer, a silicon nitride layer, a silicon oxy nitride layer, an aluminum oxide layer, a zirconium oxide layer, a hafnium oxide layer, and/or a titanium oxide layer.

Thereafter, the side reflective layer SRL on the side insulating layer SI and overlapping the light emitting diodes LED may be formed. Each side reflective layer SRL may cover a portion of the side insulating layer SI, which overlaps the light emitting diode LED. The side reflective layer SRL may include gold (Au), copper (Cu), silver (Ag), titanium (Ti), and/or aluminum (Al).

Thereafter, openings S-H1, S-H2, and S-H3 passing through the first and second side insulating layers SI1 and SI2 and the side reflective layer SRL may be formed. The openings S-H1, S-H2, and S-H3 may expose the upper surface of the second electrode part ES2 of the light emitting diode LED formed in the display area DA. The openings S-H1, S-H2, and S-H3 may be defined as the first opening S-OP.

Thereafter, the method may include an operation of forming the flattening layer 140 on the second insulating layer 130. The flattening layer 140 may include a silicon oxide. The flattening layer 140 may be formed by a chemical vapor deposition (CVD) process. The flattening layer 140 may cover the light emitting diodes LED.

The upper surface of the initially formed flattening layer 140 may be non-uniform. Thus, a process of flattening the flattening layer 140 may be performed. The flattening process may be performed by the CMP process in the damascene method. In the CMP process, the flattening layer 140 may be polished by applying pressure to a rotating polishing machine RH. In this case, slurry SL, which is a type of polishing liquid, may be applied to prevent damage to the flattening layer 140.

Referring to FIG. 13B, the method may include an operation of patterning the flattening layer 140. The trench TR may be formed by patterning an area of the flattening layer 140 between the light emitting diodes LED. The patterning process may be performed by a dry etching process.

Referring to FIGS. 13C and 13D, the method may include an operation of forming the barrier layer SE2-2 covering the trench TR and an operation of forming the metal structure SE2-1.

The barrier layer SE2-2 may include the barrier metal layer and the barrier metal nitride layer. The barrier metal nitride layer may be formed closer to the flattening layer 140 than the barrier metal layer. The barrier metal layer may include titanium and/or tantalum. The barrier metal nitride layer may include a titanium nitride layer and/or a tantalum nitride layer.

The initial metal structure SE2-1 may be formed on the flattening layer 140 and may be formed inside the trench TR covered with the barrier layer SE2-2.

Thereafter, a process of patterning the initial metal structure SE2-1 may be included. The patterning may be performed through the CMP process. The initial metal structure SE2-1 may include a metal such as copper and/or tungsten.

After the CMP process is performed on the initial metal structure SE2-1, the metal structure SE2-1 may be formed only inside the trench TR. The barrier layer SE2-2 and the metal structure SE2-1 may be defined as the second auxiliary electrode SE2. The first auxiliary electrode SE1 described in FIG. 5 may also be formed by the same process as the second auxiliary electrode SE2. The first auxiliary electrode SE1 and the second auxiliary electrode SE2 on a plane may have lattice shapes described in FIGS. 4 and 5.

As illustrated in FIG. 13D, when the CMP process is performed on the initial metal structure SE2-1, the flattening layer 140 may be further polished than the initial metal structure SE2-1, and thus a dishing phenomenon may occur in the flattening layer 140. The grooves GR recessed in a direction from the upper surface of the flattening layer 140 toward the light emitting diodes LED may be formed in the flattening layer 140. That is, the grooves GR may be formed by the dishing phenomenon.

Referring to FIG. 13E, the method may include an operation of forming the initial lens patterns LS on the flattening layer 140 and an operation of patterning the initial lens patterns LS. According to one or more embodiments of the present disclosure, the refractive index of the flattening layer 140 may be greater than the refractive index of the initial lens patterns LS. When the flattening layer 140 includes a silicon oxide, the initial lens patterns LS may include a silicon nitride.

The initial lens patterns LS may be formed by the CVD process.

Thereafter, a process of individually patterning the initial lens patterns LS formed as an integral layer may be performed. The patterning process may be performed through the CMP process in the damascene method. In the CMP process, the initial lens patterns LS may be polished by applying pressure to the rotating polishing machine RH.

Referring to FIG. 13F, the lens patterns LS may be formed by patterning the initial lens patterns LS. The lens patterns LS may be individually patterned on the light emitting diodes.

One patterned lens pattern LS may be disposed inside one groove GR. In this case, the upper surface of the second auxiliary electrode SE2, the upper surface of the flattening layer 140, and upper surfaces of the lens patterns LS may define the same plane.

Thereafter, the method may include an operation of forming the openings OP. The opening OP may be formed by aligning the first opening S-OP, the second opening 140-OP, and the third opening L-OP. The first opening S-OP may include the (1-1)^{th} opening S-H1 formed in the second side insulating layer SI2, the (1-2)^{th} opening S-H2 formed in the first side insulating layer SI1, and the (1-3)^{th} opening S-H3 formed in the side reflective layer SRL. The second opening 140-OP may be formed in the flattening layer 140, and the third opening L-OP may be formed in the lens pattern LS.

Referring to FIG. 13G, the method may include an operation of forming the common electrode CME and an operation of forming the passivation layer 150.

The common electrode CME may be in contact with the upper surface of the second auxiliary electrode SE2, the upper surface of the flattening layer 140, and the upper surfaces of the lens patterns LS. Further, the common electrode CME may be in contact with a side surface of the side insulating layer SI defining the first opening S-OP, a side surface of the flattening layer 140 defining the second opening 140-OP, and a side surface of the lens patterns LS defining the third opening L-OP. The common electrode CME may be in contact with the second electrode part ES2 through the opening OP.

The passivation layer 150 may be formed on the common electrode CME and may compensate for a step difference formed by components arranged under the passivation layer 150. Thus, the upper surface of the passivation layer 150 may provide a flat surface. The passivation layer 150 may include a silicon nitride, and the refractive index of the passivation layer 150 may be equal to or lower than the refractive index of the flattening layer 140.

According to one or more embodiments of the present disclosure, as the lens patterns LS having a light condensing function are formed in a dishing area formed by the CMP process, a separate photo process is not required, and thus a mask reduction effect may be obtained. Further, when separate lens patterns are formed, misalignment that may occur between the light emitting diode and the lens pattern may not be considered. Accordingly, the method of manufacturing a display device, having improved process yield and reduced manufacturing cost, may be provided.

Although the description has been made above with reference to some embodiments of the present disclosure, it may be understood that those skilled in the art or those having ordinary knowledge in the art may variously modify and change the present disclosure without departing from the spirit and technical scope of the present disclosure described in the appended claims and their equivalents.

Thus, the technical scope of the present disclosure is not limited to the detailed description of the specification but may be defined by the appended claims and their equivalents.

What is claimed is:

1. A display device comprising:
a complementary metal oxide semiconductor (CMOS) wafer including:
a display area including unit areas and a boundary area between the unit areas, the display area having a lattice shape; and
a non-display area adjacent to the display area;
light emitting diodes overlapping the unit areas;
a flattening layer covering the light emitting diodes;
an auxiliary electrode overlapping the boundary area and located in the flattening layer;
a common electrode on the flattening layer and connected to the auxiliary electrode and the light emitting diodes; and
a passivation layer covering the common electrode,
wherein grooves recessed in a direction from an upper surface of the flattening layer toward the light emitting diodes are in the flattening layer overlapping the unit areas.

2. The display device of claim 1, further comprising:
lens patterns in the grooves, respectively.

3. The display device of claim 2, wherein the flattening layer comprises a silicon oxide, and
wherein the lens patterns comprise a silicon nitride.

4. The display device of claim 3, wherein a refractive index of the flattening layer is greater than a refractive index of the lens patterns.

5. The display device of claim 4, wherein the refractive index of the flattening layer is in a range of 1.5 to 1.6, and
wherein the refractive index of the lens patterns is in a range of 1.4 to 1.5.

6. The display device of claim 3, wherein the lens patterns have a relatively higher density than a density of the flattening layer.

7. The display device of claim 2, wherein an upper surface of the auxiliary electrode and upper surfaces of the lens patterns in contact with the common electrode are in a same plane.

8. The display device of claim 2, wherein each of the grooves on a cross section has one of a semi-elliptical shape, a triangular shape, or a quadrangular shape,
wherein a shape of each of the lens patterns on a cross section has a shape corresponding to a shape of the groove.

9. The display device of claim 2, further comprising:
a first side insulating layer covering the light emitting diodes; and
second side insulating layers arranged between the light emitting diodes and the first side insulating layer and covering the light emitting diodes.

10. The display device of claim 9, further comprising:
a side reflective layer on the first side insulating layer and overlapping the light emitting diodes.

11. The display device of claim 10, wherein the common electrode is connected to the light emitting diodes through an opening passing through the first side insulating layer, the second side insulating layer, the side reflective layer, the flattening layer, and the lens pattern.

12. The display device of claim 2, wherein the passivation layer compensates for a step difference in the display device due to components arranged under the passivation layer, and an upper surface of the passivation layer has a flat surface.

13. The display device of claim 1, wherein the common electrode is in contact with the auxiliary electrode in the boundary area, is in the grooves in the unit areas, and is in contact with the flattening layer.

14. The display device of claim 13, wherein the flattening layer comprises a silicon oxide, and
wherein the passivation layer comprises a silicon nitride.

15. The display device of claim 13, wherein the passivation layer is on the common electrode to correspond to a shape of the common electrode.

16. The display device of claim 13, further comprising:
a lens layer on the passivation layer and overlapping the boundary area and the unit areas,
wherein a refractive index of the lens layer is smaller than a refractive index of the flattening layer.

17. The display device of claim 16, wherein the lens layer is a mixture of an organic material and hollow silica.

18. The display device of claim 16, wherein a refractive index of the passivation layer is equal to or smaller than the refractive index of the flattening layer.

19. The display device of claim 1, wherein the CMOS wafer comprises:
a silicon substrate which is connected to the light emitting diodes and in which a source area or a drain area is defined;
a gate on the silicon substrate;
a first insulating layer covering the gate and on the silicon substrate;
a first contact electrode connected to the source area or the drain area through a first contact hole defined in the first insulating layer;
a second insulating layer covering the first contact electrode and on the first insulating layer; and
a second contact electrode connected to the first contact electrode through a second contact hole passing through the second insulating layer.

20. An electronic device comprising a display device, the display device comprising:
a complementary metal oxide semiconductor (CMOS) wafer including:
a display area including unit areas and a boundary area between the unit areas, the display area having a lattice shape; and
a non-display area adjacent to the display area;
light emitting diodes overlapping the unit areas;
a flattening layer covering the light emitting diodes;
an auxiliary electrode overlapping the boundary area and located in the flattening layer;
a common electrode on the flattening layer and connected to the auxiliary electrode and the light emitting diodes; and
a passivation layer covering the common electrode,
wherein grooves recessed in a direction from an upper surface of the flattening layer toward the light emitting diodes are in the flattening layer overlapping the unit areas.
